(19) United States
(12) Patent Application Publication
(10) Pub. No.: US 2025/0324832 A1
(43) Pub. Date: Oct. 16, 2025

(54) DISPLAY DEVICE AND METHOD FOR MANUFACTURING THE SAME

(71) Applicant: Samsung Display Co., LTD., Yongin-si (KR)

(72) Inventors: You Young JIN, Yongin-si (KR); Keun Chan OH, Yongin-si (KR); Jae Cheol PARK, Yongin-si (KR); Sun-Kyu JOO, Yongin-si (KR)

(21) Appl. No.: 19/011,208

(22) Filed: Jan. 6, 2025

(30) Foreign Application Priority Data
Apr. 11, 2024 (KR) 10-2024-0048747

(51) Int. Cl. H10H 29/37; H10H 29/01; H10H 29/80; H10H 29/851

(52) U.S. Cl. CPC H10H 29/37; H10H 29/012; H10H 29/8512; H10H 29/882

(57) ABSTRACT

A display device includes: a display unit including a plurality of light emitting diodes; a color conversion unit including a bank and a color conversion layer; and an adhesive cell gap maintenance layer between the display unit and the color conversion unit, wherein the adhesive cell gap maintenance layer includes an adhesive cell gap maintenance part, and the adhesive cell gap maintenance part includes a beads spacer and an adhesive organic material.

### CROSS-REFERENCE TO RELATED APPLICATION

The present application claims priority to and the benefit of Korean Patent Application No. 10-2024-0048747, filed on Apr. 11, 2024, in the Korean Intellectual Property Office, the entire disclosure of which is incorporated herein by reference.

### BACKGROUND

### 1. Field

Aspects of some embodiments of the present disclosure relate to a display device and a method of manufacturing the display device.

### 2. Description of the Related Art

As display devices, a light emitting display device that displays images by adjusting the brightness of light emitting elements and a liquid crystal display device that displays images by adjusting the transmittance of a liquid crystal layer may be used. Unlike liquid crystal display devices, light emitting display devices generally do include a separate light source such as a backlight, so the thickness and weight of the light emitting display device may be relatively reduced. Additionally, light emitting display devices generally exhibit relatively high-quality characteristics such as relatively low power consumption, high brightness, and high response speed.

Display devices including a color conversion unit may reduce light loss and implement and have a relatively high color reproduction rate. The color conversion unit may include color conversion layers in which quantum dots are dispersed, and simplification of the process of protecting this layer may be desired.

The above information disclosed in this Background section is only for enhancement of understanding of the background and therefore the information discussed in this Background section does not necessarily constitute prior art.

### SUMMARY

Aspects of some embodiments of the present disclosure include a display device that may have a relatively simplied manufacturing process, relatively reduced costs, and relatively improved light efficiency.

Aspects of some embodiments of the present disclosure include a method of manufacturing the display device that may have relatively reduced costs and a relatively simplified manufacturing process.

A display device according to some embodiments includes a display unit including a plurality of light emitting diodes, a color conversion unit including a bank and a color conversion layer, and an adhesive cell gap maintenance layer between the display unit and the color conversion unit, wherein the adhesive cell gap maintenance layer includes an adhesive cell gap maintenance part, and the adhesive cell gap maintenance part includes a beads spacer and an adhesive organic material.

According to some embodiments, the color conversion unit further includes a transmission layer, and the adhesive cell gap maintenance part may be on at least one of the color conversion layer and the transmission layer.

According to some embodiments, a portion of the adhesive cell gap maintenance part may include the adhesive cell gap maintenance layer overlapping the bank.

According to some embodiments, the color conversion unit may further include a well, and the adhesive cell gap maintenance part may be within the well.

According to some embodiments, an air gap may be formed in the adhesive cell gap maintenance layer where the adhesive cell gap maintenance part is not filled.

According to some embodiments, the height of the bank may be higher than the color conversion layer.

According to some embodiments, the adhesive cell gap maintenance part may be in contact with the color conversion layer and the bank.

According to some embodiments, the color conversion unit may further include a transmission layer, the color conversion layer may include quantum dots and scatterers, and the transmission layer may include scatterers.

a display device according to some embodiments includes a substrate, a plurality of light emitting diodes on the substrate, an encapsulation layer on the plurality of light emitting diodes, a color conversion unit including a bank and a color conversion layer on the encapsulation layer, an adhesive cell gap maintenance part including a beads spacer and an adhesive organic material on the color conversion part, an adhesive cell gap maintenance layer including the adhesive cell gap maintenance part, and a color filter on the adhesive cell gap maintenance layer.

According to some embodiments, the color conversion unit further includes a transmission layer, and the adhesive cell gap maintenance part may be on at least one of the color conversion layer or the transmission layer.

According to some embodiments, a portion of the adhesive cell gap maintenance part may include the adhesive cell gap maintenance layer overlapping the bank.

According to some embodiments, the air gap may be formed in the adhesive cell gap maintenance layer where the adhesive cell gap maintenance part is not filled.

According to some embodiments, the height of the bank may be higher than the color conversion layer.

According to some embodiments, the adhesive cell gap maintenance part may be in contact with the color conversion layer and the bank.

According to some embodiments, the color conversion unit may further include a transmission layer, the color conversion layer may include quantum dots and scatterers, and the transmission layer may include scatterers.

In a method for manufacturing a display device according to some embodiments, the method includes the steps of forming a bank including a color conversion layer and a transmission layer, applying an adhesive cell gap maintenance part that includes beads spacers and an adhesive organic material on at least one of the color conversion layer or the transmission layer, bonding the display unit onto the adhesive cell gap maintenance part, and curing the adhesive cell gap maintenance part to form an adhesive cell gap maintenance layer.

According to some embodiments, in curing the adhesive cell gap maintenance part, the adhesive cell gap maintenance layer may be formed on any one of the color conversion layer, the transmission layer, or the bank.

According to some embodiments, in curing the adhesive cell gap maintenance part, a portion of the adhesive cell gap maintenance part may overlap the bank to form the adhesive cell gap maintenance layer.

According to some embodiments, the bank further includes a well, and in the step of curing the adhesive cell gap maintenance part, a portion of the adhesive cell gap maintenance part may remain in the well and form the adhesive cell gap maintenance layer.

According to some embodiments, in curing the adhesive cell gap maintenance part, an air gap may be formed in a space not filled by the adhesive cell gap maintenance part.

According to some embodiments, the manufacturing process may be relatively simplified and costs may be relatively reduced by providing the display device including a beads spacer and an adhesive organic material. Additionally, according to some embodiments, the luminous efficiency of the display device may be relatively improved by forming the air gap.

### BRIEF DESCRIPTION OF THE DRAWINGS

FIG. 1 is a schematic plan view of a display device according to some embodiments.

FIG. 2 is a schematic plan view of a display area in a display panel according to some embodiments.

FIG. 3 is a cross-sectional view taken along the line A-A′ in FIG. 2 according to some embodiments.

FIG. 4 is a cross-sectional view taken along the line A-A′ in FIG. 2 according to some embodiments.

FIG. 5 is a cross-sectional view taken along the line A-A′ in FIG. 2 according to some embodiments.

FIGS. 6 to 10 are cross-sectional views schematically showing the manufacturing process of a display panel according to some embodiments.

FIG. 11 is a cross-sectional view taken along the line A-A′ in FIG. 2 according to some embodiments.

FIG. 12 is a cross-sectional view taken along the line A-A′ in FIG. 2 according to some embodiments.

FIG. 13 is a cross-sectional view taken along the line A-A′ in FIG. 2 according to some embodiments.

FIG. 14 to FIG. 18 are cross-sectional views schematically showing the manufacturing process of a display panel according to some embodiments.

FIG. 19 is a schematic plan view of a display area in a display panel according to some embodiments.

FIG. 20 is a cross-sectional view taken along the line B-B′ in FIG. 19 according to some embodiments.

FIG. 21 is a cross-sectional view taken along the line B-B′ in FIG. 19 according to some embodiments.

FIG. 22 is a cross-sectional view taken along the line B-B′ in FIG. 19 according to some embodiments.

FIG. 23 is a cross-sectional view taken along the line B-B′ in FIG. 19 according to some embodiments.

FIG. 24 is a circuit diagram of one pixel of a display device according to some embodiments.

### DETAILED DESCRIPTION

Hereinafter, with reference to the attached drawings, various embodiments of the present disclosure will be described in more detail so that those skilled in the art can easily implement the present disclosure. The invention may be implemented in many different forms and is not limited to the embodiments described herein.

In order to more clearly explain aspects of some embodiments of the present disclosure, descriptions of some components that are not necessary to enable a person having ordinary skill in the art to make, use, and understand embodiments according to the present disclosure may be omitted, and identical or similar components are assigned the same reference numerals throughout the specification.

In addition, the size and thickness of each component shown in the drawings are arbitrarily shown for convenience of explanation, so the present disclosure is not necessarily limited to that which is shown. In the drawings, the thickness is enlarged to clearly express various layers and regions. And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part means being located above or below the reference part, and does not necessarily mean being located “above” or “on” it in the direction opposite to gravity.

In addition, throughout the specification, when a part is said to “include” a certain component, this means that it may further include other components rather than excluding other components, unless specifically stated to the contrary.

In addition, throughout the specification, when reference is made to “on a plane,” this means when the target part is viewed from above, and when reference is made to “in cross-section,” this means when a cross-section of the target portion is cut vertically and viewed from the side.

In addition, throughout the specification, when “connected” is used, this does not mean only when two or more components are directly connected, but also when two or more components are indirectly connected through other components, physically connected or electrically connected, as well as when referred to by different names depending on location or function, but may include practically integrated parts connected to each other.

In addition, throughout the specification, when a portion such as a wiring, layer, film, region, plate, or component is said to “extend in the first or second direction,” this does not mean only a straight shape extending in that direction, but also structures that are curved, zigzagged or otherwise extend along the first or second direction.

In addition, electronic devices (e.g., mobile phones, TVs, monitors, laptop computers, etc.) containing display devices, display panels, etc. described in the specification, or display devices, display panels, etc. manufactured by the manufacturing method described in the specification included herein are not excluded from the scope of rights of this specification.

In the drawings, the symbols “x,” “y,” and “z” are used to indicate directions, where “x” is the first direction, “y” is the second direction perpendicular to the first direction, and “z” is the third direction perpendicular to both the first and second directions. The first direction x, the second direction y, and the third direction z may correspond to the horizontal direction, vertical direction, and thickness direction of the display device, respectively.

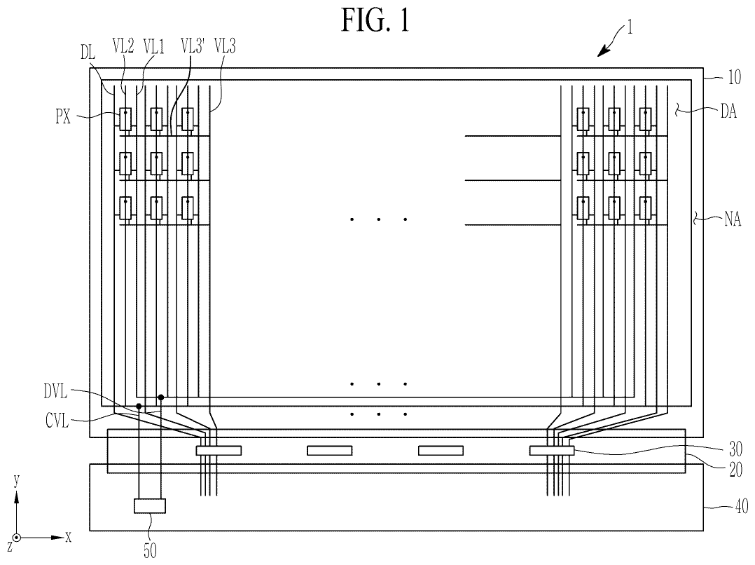

FIG. 1 is a schematic plan view of the display device according to some embodiments.

Referring to FIG. 1, the display device 1 may include a display panel 10, a flexible printed circuit board 20, a driving integrated circuit chip 30, a printed circuit board 40, a power module 50, etc.

The display panel 10 may include a display area DA, which corresponds to the screen displaying the image, and a non-display area NA where various circuits and/or wirings that generate and/or transmit signals applied to the display area DA are arranged. The non-display area NA may be adjacent to (e.g., in a periphery or outside a footprint of) the display area DA and may surround the display area DA. In FIG. 1, the inner and outer areas of the rectangle may be a display area DA and a non-display area NA, respectively.

Pixels PX may be arranged in a matrix in the display area DA of the display panel 10. In addition, the display area DA includes a data line DL that transmits the data voltage VDATA, a driving voltage line VL1 that transmits a driving voltage ELVDD, a common voltage line VL2 that transmits a common voltage ELVSS, and an initialization voltage line VL3 transmitting an initialization voltage VINT. The driving voltage line VL1, the common voltage line VL2, and the initialization voltage line VL3 may extend in the second direction y. The initialization voltage line VL3 may include a branch voltage line VL3′ extending in the first direction x. Each pixel PX may receive a data voltage VDATA, a driving voltage ELVDD, a common voltage ELVSS, and an initialization voltage VINT from these wires. The driving voltage ELVDD and the common voltage ELVSS are power voltages applied to each pixel PX, and the driving voltage line VL1 and the common voltage line VL2 that transmit these power voltages may be called power voltage lines. The driving voltage ELVDD may be a higher voltage than the common voltage ELVSS. The driving voltage ELVDD may be called a first power supply voltage or a high-potential power supply voltage. The common voltage ELVSS may be called a second power supply voltage or a low-potential power supply voltage.

In the non-display area NA of the display panel 10, gate drivers may be located on both sides of the display area DA. The gate driver may be integrated in the non-display area NA. The pixel PX may receive a data voltage VDATA at a set or predetermined timing by receiving a gate signal (also called a scan signal) generated by the gate driver.

A driving voltage transmission line DVL connected to the driving voltage lines VL1, and a common voltage transmission line CVL connected to the common voltage lines VL2 may be located in the non-display area NA of the display panel 10. The driving voltage transmission line DVL and the common voltage transmission line CVL may include portions extending approximately in the second direction y and portions extending approximately in the first direction x, respectively. The common voltage transmission line CVL may be positioned to surround (e.g., in a periphery or outside a footprint of) the display area DA. The common voltage lines VL2 may be connected to the common voltage transmission line CVL at the lower and upper sides of the display area DA, thereby supplying the common voltage uniformly throughout the entire display area DA.

One end of the flexible printed circuit board 20 may be connected or bonded to the display panel 10, and the other end may be connected or bonded to the printed circuit board 40. A driving integrated circuit chip 30 including a data driver that applies a data voltage VDATA to the data line DL may be located on the flexible printed circuit board 20.

A power module 50 that generates power voltages such as a driving voltage ELVDD and a common voltage ELVSS may be located on the printed circuit board 40. The power module 50 may be provided in the form of an integrated circuit chip. A signal control unit that controls the data driver and the gate driver may be located on the printed circuit board 40.

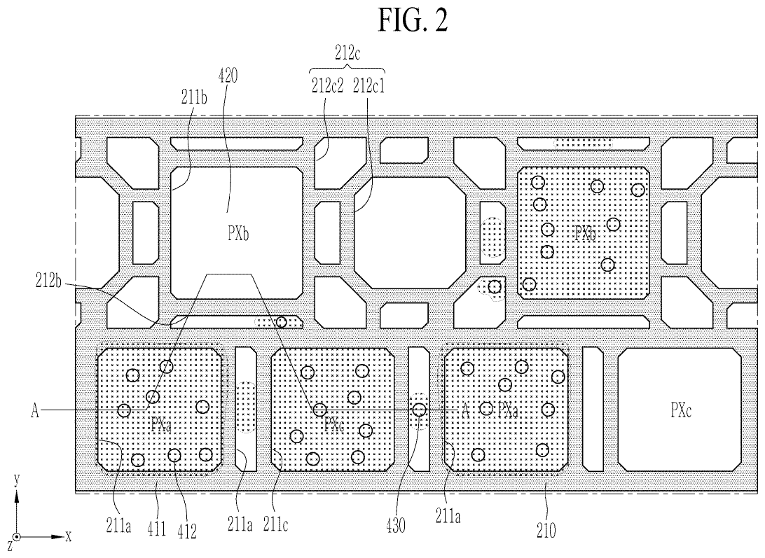

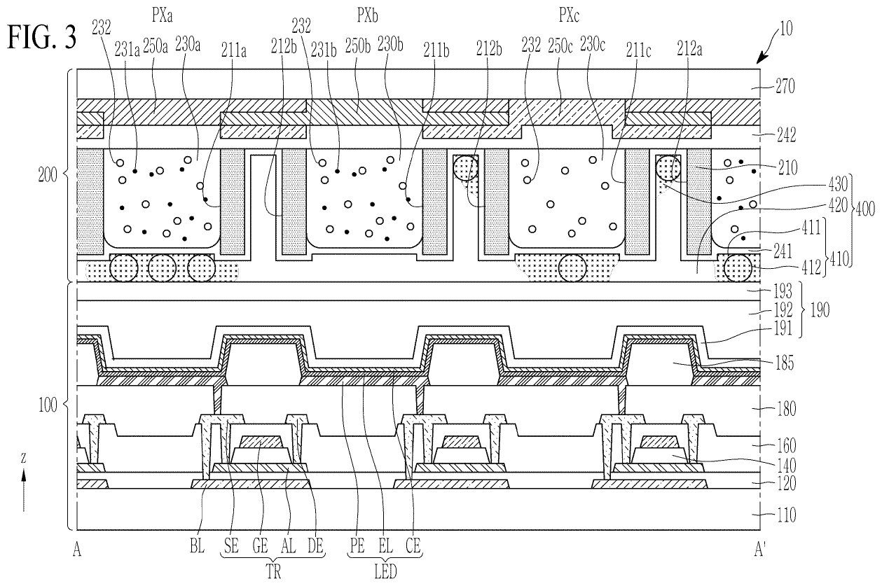

FIG. 2 is a schematic plan view of a display area in a display panel according to some embodiments, and FIG. 3 is a cross-sectional view taken along the line A-A′ in FIG. 2 according to some embodiments.

Referring to FIG. 2, an area in the display area DA where approximately six pixels PXa, PXb, PXc are arranged is shown. The pixels PXa, PXb, PXc may include a first pixel PXa, a second pixel PXb, and a third pixel PXc representing different colors. For example, the first pixel PXa may emit red light, the second pixel PXb may emit green light, and the third pixel PXc may emit blue light. In the display area DA, the first pixel PXa, second pixel PXb, and third pixel PXc may be repeatedly arranged in the first direction x and the second direction y.

Referring to FIG. 3, the display panel 10 may include a display unit 100 and a color conversion unit 200. The color conversion unit 200 may be located on the display unit 100, and the entire color conversion unit 200 may overlap the display unit 100.

The display unit 100 may include a light emitting diode LED corresponding to each pixel PXa, PXb, PXc. The color conversion unit 200 may convert the wavelength of light emitted from a light emitting diode LED and emit it to the outside of the display panel 10.

The display unit 100 may basically include a lower substrate 110, a transistor TR formed on the lower substrate 110, and a light emitting diode LED connected to the transistor TR.

The lower substrate 110 may include a material with rigid properties such as glass, or a material with flexible properties such as plastic. For example, the lower substrate 110 may be a glass substrate.

A light blocking layer BL may be positioned on the lower substrate 110. The light blocking layer BL prevents or reduces instances of external light reaching the semiconductor layer AL of the transistor TR and prevents or reduces deterioration of the characteristics of the semiconductor layer AL. The light blocking layer BL may control the leakage current of the transistor TR, especially the driving transistor, whose current characteristics are important in light emitting display devices. The light blocking layer BL may include a material that does not transmit light in the wavelength range to be blocked. For example, the light blocking layer BL may include metals such as copper (Cu), aluminum (Al), molybdenum (MO), titanium (Ti), and tungsten (W), and may be a single layer or multiple layers. For example, the light blocking layer BL may have a double-layer structure such as titanium (Ti)/copper (Cu). The light blocking layer BL may function as an electrode to which a specific voltage is applied to the display panel 10. In this case, the current change rate becomes smaller in the saturation region of the voltage-current characteristic graph of the transistor TR, thereby improving the characteristics as a driving transistor.

A buffer layer 120 may be located on the lower substrate 110 and the light blocking layer BL. The buffer layer 120 may block impurities from the lower substrate 110 during the formation of the semiconductor layer AL, improving the characteristics of the semiconductor layer AL, and may relieve the stress of the semiconductor layer AL by flattening the surface of the lower substrate 110. The buffer layer 120 may include an inorganic insulating material such as silicon nitride SiNₓ, silicon oxide SiOₓ, or silicon oxynitride SiOₓN_{y}. The buffer layer 120 may include amorphous silicon.

The semiconductor layer AL may be located on the buffer layer 120. The semiconductor layer AL may include a first region, a second region, and a channel region between these regions. The semiconductor layer AL may include an oxide semiconductor. For example, the semiconductor layer (AL) may include an oxide semiconductor such as IGZO (indium-gallium-zinc oxide), which includes at least one of zinc (Zn), indium (In), gallium (Ga), tin (Sn), or mixtures thereof. The semiconductor layer AL may include polycrystalline silicon or amorphous silicon—for example, low-temperature polysilicon LTPS.

A gate insulating layer 140 may be located on the semiconductor layer AL. The gate insulating layer 140 may be formed in an area that overlaps the gate electrode GE. This structure may be formed by etching the gate insulating layer 140 during a photolithography process to form the gate electrode GE. Alternatively, it may be formed to cover substantially the entire lower substrate 110. The gate insulating layer 140 may include an inorganic insulating material such as silicon oxide, silicon nitride, or silicon oxynitride, and may be a single layer or multiple layers.

A gate electrode GE may be positioned on the gate insulating layer 140. The gate electrode GE may overlap the channel region of the semiconductor layer AL. The gate electrode GE may contain a metal such as molybdenum (Mo), aluminum (Al), copper (Cu), or titanium (Ti), and may be a single layer or a multilayer. For example, the gate insulating layer 140 may have a double-layer structure such as titanium (Ti)/copper (Cu). The above-described first gate line GL1 and/or second gate line GL2 may be on the same layer as the gate electrode GE. As used herein, being formed of the same layer or the same layer may mean that the corresponding components are formed of the same material in the same process (e.g., the same photolithography process).

An interlayer insulating layer 160 may be positioned on the gate electrode GE. The interlayer insulating layer 160 may include an inorganic insulating material such as silicon oxide, silicon nitride, or silicon oxynitride, and may be a single layer or multiple layers.

The first electrode SE and the second electrode DE of the transistor TR may be positioned on the interlayer insulating layer 160. One of the first electrode SE and the second electrode DE may be a source electrode of the transistor TR, and the other may be a drain electrode of the transistor TR. The first electrode SE and the second electrode DE may be respectively connected to the first and second regions of the semiconductor layer AL through contact holes formed in the interlayer insulating layer 160. The first electrode SE or the second electrode DE may be connected to the light blocking layer BL through contact holes formed in the interlayer insulating layer 160, the gate insulating layer 140, and the buffer layer 120. The first electrode SE and the second electrode DE may include metals such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), and may be either a single layer or multiple layers. For example, the first electrode SE and the second electrode DE may have a dual-layer structure such as titanium (Ti)/copper (Cu), or a triple-layer structure such as titanium (Ti)/aluminum (Al)/titanium (Ti).

The above-described data line DL, driving voltage line VL1, common voltage line VL2, initialization voltage line VL3, driving voltage transfer line DVL, and/or common voltage transfer line CVL may be in the same layer as the first electrode SE and the second electrode DE.

The semiconductor layer AL, gate electrode GE, first electrode SE, and second electrode DE may form a transistor TR. The illustrated transistor TR may correspond to a first transistor T1 in the pixel PX of FIG. 2.

A planarization layer 180 may be positioned on the first electrode SE and the second electrode DE. The planarization layer 180 may include organic insulating materials such as general-purpose polymers like poly (methyl methacrylate), polystyrene, polymer derivatives containing phenolic groups, acrylic polymers, imide polymers (for example, polyimide), and siloxane polymers.

A pixel electrode PE of a light emitting diode LED may be located on the planarization layer 180. The pixel electrode PE may be connected to the second electrode DE through a contact hole formed in the planarization layer 180. The pixel electrode PE may be formed of a reflective conductive material or a semi-transparent conductive material, or may be formed of a transparent conductive material. The pixel electrode PE may include a transparent conductive material such as indium tin oxide ITO or indium zinc oxide IZO. The pixel electrode PE may include metal such as lithium (Li), calcium (Ca), aluminum (Al), silver (Ag), magnesium (Mg), and gold (Au). The pixel electrode PE may have a multi-layer structure—for example, a triple-layer structure such as ITO/silver (Ag)/ITO.

A pixel defining layer 185 having an opening that overlaps the pixel electrode PE may be positioned on the planarization layer 180. The pixel defining layer 185 may include an organic insulating material such as an acrylic polymer, an imide polymer, or an amide polymer. The pixel defining layer 185 may include colored pigments, such as black pigments and blue pigments. For example, the pixel defining layer 185 may include a polyimide binder and a pigment mixed with red, green, and blue. The pixel defining layer 185 may include a cardo binder resin and a mixture of lactam black pigment and blue pigment. The pixel defining layer 185 may include carbon black. The pixel defining layer 185 containing black pigment may improve contrast ratio and prevent or reduce reflection by the metal layer located below.

A light emitting layer EL may be located on the pixel electrode PE and the pixel defining layer 185. The light emitting layer EL may contact the pixel electrode PE through the opening of the pixel defining layer 185. Unlike shown, the light emitting layer EL may be located within the opening of the pixel defining layer 185. The light emitting layer EL may include a light emitting material that emits blue light. The light emitting layer EL may include a light emitting material that emits red light or green light in addition to blue light. In addition to the light emitting layer EL, at least one of a hole injection layer, a hole transport layer, an electron transport layer, or an electron injection layer may be positioned on the pixel electrode PE.

A common electrode CE may be located on the light emitting layer EL. The common electrode CE may be arranged or formed across the pixels PXa, PXb, PXc. The common electrode CE may include metals such as calcium (Ca), barium (Ba), magnesium (Mg), aluminum (Al), silver (Ag), platinum (Pt), palladium (Pd), gold (Au), and nickel (Ni), neodymium (Nd), iridium (Ir), chromium (Cr), and lithium (Li). The common electrode CE may include a transparent conductive oxide such as indium tin oxide ITO or indium zinc oxide IZO.

The pixel electrode PE, the light emitting layer EL, and the common electrode CE may constitute a light emitting diode LED, which may be an organic light emitting diode. The pixel electrode PE is provided individually for each pixel PXa, PXb, PXc and may receive driving current. The common electrode CE operates in common with the pixels PXa, PXb, PXc and may receive a common voltage. The pixel electrode PE may be an anode, which is a hole injection electrode, and the common electrode CE may be a cathode, which is an electron injection electrode, or vice versa. The opening of the pixel defining layer 185 may correspond to the light emitting area of a light emitting diode LED.

A display encapsulation layer 190 (hereinafter simply referred to as an encapsulation layer) may be positioned on the common electrode CE. The encapsulation layer 190 may seal the light emitting diodes LEDs and prevent or reduce instances of contaminants such as moisture or oxygen penetrating from the outside. The encapsulation layer 190 covers the entire display area DA, and an edge of the encapsulation layer 190 may be located in the non-display area NA. The encapsulation layer 190 may be a thin-film encapsulation layer including a first inorganic layer 191, a second inorganic layer 193, and an organic layer 192. The first inorganic layer 191 and the second inorganic layer 193 mainly prevent or reduce the penetration of contaminants such as moisture, etc., and the organic layer 192 mainly flatten the surface of the encapsulation layer 190, especially the surface of the second inorganic layer 193 in the display area DA. The first inorganic layer 191 and the second inorganic layer 193 may include an inorganic insulating material such as silicon oxide or silicon nitride. The organic layer 192 may include organic materials such as acrylic resin, methacrylic resin, polyisoprene, vinyl resin, epoxy resin, urethane resin, cellulose resin, and perylene resin.

The color conversion unit 200 may include a bank 210, first and second color conversion layers 230a, 230b, a transmission layer 230c, first and second insulating layers 241, 242, color filters 250a, 250b, 250c, and an upper substrate 270. The color conversion unit 200 may be coupled to the display unit 100 through the adhesive cell gap maintenance layer 400.

The bank 210 may be located on the lower surface of the second insulating layer 242 of the color conversion unit 200. For example, the upper surface of the bank 210 may contact the lower surface of the second insulating layer 242. According to some embodiments, the second insulating layer 242 may be omitted and may be in contact with the color filters 250a, 250b, and 250c. The bank 210 may overlap the pixel defining layer 185. The bank 210 may not overlap or barely overlaps the light emitting diodes LEDs. The bank 210 may be located at the boundary of the pixels PXa, PXb, PXc. The bank 210 may partition the pixel area.

Referring to FIG. 2, the bank 210 may include openings 211a, 211b, and 211c that overlap the light emitting diodes LEDs. The bank 210 may include wells 212a, 212b, and 212c that overlap the pixel defining layer 185. Expressed differently, the openings 211a, 211b, and 211c and the wells 212a, 212b, and 212c may be included in the bank 210.

The openings 211a, 211b, and 211c may penetrate the bank 210 in the third direction z. The openings 211a, 211b, 211c may include a first opening 211a overlapping a light emitting diode LED corresponding to the first pixel PXa, a second opening 211b overlapping a light emitting diode LED corresponding to the second pixel PXb, and a third opening 211c overlapping a light emitting diode LED corresponding to the third pixel PXc.

The wells 212a, 212b, and 212c may penetrate the bank 210 in the third direction z. The wells 212a, 212b, and 212c may include a first well 212a located between the first pixel PXa and the third pixel PXc, a second well 212b located between the second pixel PXb and the first and third pixels PXa, PXc, and a third well 212c located between adjacent second pixels PXb. The first well 212a may be elongated in the first direction x, and the second well 212b may be elongated in the second direction y. The third well 212c may be formed over a larger area than each of the first well 212a and the second well 212b. The third well 212c may be formed over a larger area than each of the first opening 211a, the second opening 211b, and the third opening 211c. The wells 212a, 212b, and 212c are separate from each other, but may be connected. For example, the first well 212a and the second well 212b may be connected to form a T-shaped planar shape. The arrangement, size, and shape of the wells 212a, 212b, and 212c may vary depending on the arrangement, size, and shape of the pixels PXa, PXb, PXc.

The bank 210 may have liquid repellency. The bank 210 may be formed of a photosensitive resin composition containing a liquid-repellent material, or the surface of the bank 210 may be subjected to a liquid-repelling treatment (e.g., plasma treatment) after forming the bank 210. The bank 210 may include organic materials such as acrylic polymer, epoxy polymer, imide polymer, olefin polymer, and amide polymer. Due to the liquid repellency of the bank 210, during the inkjet process for forming the first and second color conversion layers 230a, 230b and the transmission layer 230c, the spread of droplets misdeposited on or at the edges of the bank 210 may be controlled to prevent or reduce their stay on or at the edges of the bank 210, and the size of the misdeposited droplets may be reduced. If there are misdeposited droplets on the bank 210, they may degrade the quality (e.g., adhesion, flatness, etc.) of the layer formed in the subsequent process, so it may be necessary to remove them or reduce their size. As a way to reduce misdeposited droplets, the height of the bank 210 may be set higher than the first and second color conversion layers 230a and 230b and the transmission layer 230c.

The first color conversion layer 230a, the second color conversion layer 230b, and the transmission layer 230c may be located in the first opening 211a, the second opening 211b, and the third opening 211c, respectively. A dummy 430 may be located within the wells 212a, 212b, and 212c. The upper surfaces of the first color conversion layer 230a, the second color conversion layer 230b, and the transmission layer 230c may contact the lower surface of the second insulating layer 242. The first color conversion layer 230a, the second color conversion layer 230b, and the transmission layer 230c may be formed through an inkjet process. When forming the first and second color conversion layers 230a and 230b and the transmission layer 230c, the wells 212a, 212b, and 212c may accommodate misdeposited droplets.

The first color conversion layer 230a may overlap the light emitting diode LED corresponding to the first pixel PXa, and may convert light incident from the light emitting diode LED into light of the first wavelength. The light of the first wavelength may be red light having a maximum emission peak wavelength of about 600 nm to about 650 nm—for example, about 620 nm to about 650 nm.

The second color conversion layer 230b may overlap the light emitting diode LED corresponding to the second pixel PXb, and may convert light incident from the light emitting diode LED into light of the second wavelength. The second wavelength of light may be green light having a maximum emission peak wavelength of about 500 nm to about 550 nm—for example, about 510 nm to about 550 nm.

The transmission layer 230c may overlap the light emitting diode LED corresponding to the third pixel PXc and may transmit light incident from the light emitting diode LED. The light passing through the transmission layer 230c may be light of the third wavelength. The third wavelength of light is blue light having a maximum emission peak wavelength of about 380 nm to about 480 nm, such as greater than about 420 nm, greater than about 430 nm, greater than about 440 nm, or greater than about 445 nm, and less than or equal to about 470 nm, less than or equal to about 460 nm, or less than or equal to about 455 nm.

The first color conversion layer 230a and the second color conversion layer 230b may include first quantum dots 231a and second quantum dots 231b, respectively. For example, light incident on the first color conversion layer 230a may be converted into light of the first wavelength by the first quantum dots 231a and emitted. Light incident on the second color conversion layer 230b may be converted into light of the second wavelength by the second quantum dots 231b and emitted. The first color conversion layer 230a, the second color conversion layer 230b, and the transmission layer 230c may include scatterers 232. The scatterers 232 may improve light efficiency by scattering light incident on the first color conversion layer 230a, the second color conversion layer 230b, and the transmission layer 230c.

The scatterers 232 may be metal oxide particles and/or organic particles. Examples of metal oxides include TiO₂, ZrO₂, Al₂O₃, In₂O₃, ZnO, and SnO₂. Examples of materials for organic particles include acrylic resin and urethane resin. The scatterers 232 may scatter light in a random direction regardless of the incident direction of the incident light.

The first quantum dot 231a and the second quantum dot 231b (hereinafter referred to as semiconductor nanocrystals) may each independently include Group II-VI compounds, Group III-V compounds, Group IV-VI compounds, Group IV elements or compounds, Group I-III-VI compounds, Group II-III-VI compounds, Group I-II-IV-VI compounds, or combinations thereof.

Group II-VI compounds may be selected from a group consisting of binary compounds such as CdSe, CdTe, ZnS, ZnSe, ZnTe, ZnO, HgS, HgSe, HgTe, MgSe, MgS, and their mixtures; ternary compounds selected from a group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and their mixtures; and quaternary compounds selected from a group consisting of HgZnTeS, CdZnSeS, CdZnSeTe, CdZnSTe, CdHgSeS, CdHgSeTe, CdHgSTe, HgZnSeS, HgZnSeTe, HgZnSTe, and their mixtures. Group II-VI compounds may further include a Group III metal.

Group III-V compounds include binary compounds selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AlPAS, AlPSb, InGaP, InNP, InNAs, InNSb, InPAs, InZnP, InPSb and mixtures thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. Group III-V compounds may further include a Group II metal (e.g., InZnP).

Group IV-VI compounds include binary compounds selected from the group consisting of SnS, SnSe, SnTe, PbS, PbSe, PbTe, and mixtures thereof, a ternary compound selected from the group consisting of SnSeS, SnSeTe, SnSTe, PbSeS, PbSeTe, PbSTe, SnPbS, SnPbSe, SnPbTe, and mixtures thereof, and a quaternary element compound selected from the group consisting of SnPbSSe, SnPbSeTe, SnPbSTe, and mixtures thereof.

Group IV elements or compounds include monoelement compounds selected from the group consisting of Si, Ge, and combinations thereof and a binary compound selected from the group consisting of SiC, SiGe, and combinations thereof.

Group I-III-VI compounds may be selected from CuInSe₂, CuInS₂, CuInGaSe and CuInGaS.

Group II-III-VI compounds include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgAlSe, HgInSe, HgGaTe, HgAlTe, HgInTe, MgGaS, MgAlS, MgInS, MgGaSe, MgAlSe, MgInSe, and combinations thereof.

Group I-II-IV-VI compounds may be selected from CuZnSnSe and CuZnSnS.

Quantum dots may not contain cadmium. Quantum dots may include semiconductor nanocrystals based on Group III-V compounds including indium and phosphorus. Group III-V compounds may further contain zinc. Quantum dots may include semiconductor nanocrystals based on Group II-VI compounds including chalcogen elements (e.g., sulfur, selenium, tellurium, or combinations thereof) and zinc.

In quantum dots, the above-mentioned binary compound, ternary compound, and/or quaternary compounds may exist in the particle at a uniform concentration, or may exist in the same particle with the concentration distribution partially divided into different states. Additionally, one quantum dot may have a core/shell structure surrounding other quantum dots. The interface between the core and the shell may have a concentration gradient in which the concentration of elements present in the shell decreases toward the center.

In some embodiments, quantum dots may have a core-shell structure including a core including the nanocrystals described above and a shell surrounding the core. The shell of the quantum dots may serve as a protective layer to maintain semiconductor properties by preventing or reducing chemical denaturation of the core and/or as a charging layer to impart electrophoretic properties to the quantum dots. The shell may be a single layer or multiple layers. The interface between the core and the shell may have a concentration gradient in which the concentration of elements present in the shell decreases toward the center. Examples of the shell of quantum dots include metal or non-metal oxides, semiconductor compounds, or combinations thereof.

Oxides of metals or non-metals may be exemplified by binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄. Semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

Quantum dots may have a full width of the half maximum of the emission wavelength spectrum of about 45 nm or less, about 40 nm or less, or about 30 nm or less, and may improve color purity or color reproducibility in this range. Additionally, because the light emitted through these quantum dots is emitted in all directions, the viewing angle may be improved.

Quantum dots may have different energy band gaps between the shell material and the core material. For example, the energy bandgap of the shell material may be larger or smaller than that of the core material. Quantum dots may have a multilayer shell. In a multilayer shell, the energy band gap of the outer layer may be larger than that of the inner layer (i.e., the layer closest to the core). In a multilayer shell, the energy band gap of the outer layer may be smaller than that of the inner layer.

The shape of the quantum dots is not particularly limited. For example, the shape of the quantum dots may include a sphere, polyhedron, pyramid, multipod, square, cuboid, nanotube, nanorod, nanowire, nanosheet, or a combination thereof.

Quantum dots may include organic ligands (e.g., having hydrophobic and/or hydrophilic moieties). Organic ligand moieties may be bound to the surface of quantum dots. The organic ligand may include RCOOH, RNH₂, R₂NH, R₃N, RSH, R₃PO, R₃P, ROH, RCOOR, RPO(OH)₂, RHPOOH, R₂POOH, or combinations thereof. Here, R may independently be a C3 to C40 (for example, C5 or more and C24 or less) substituted or unsubstituted alkyl, substituted or unsubstituted alkenyl, or other substituted or unsubstituted aliphatic hydrocarbon groups of C3 to C40, substituted or unsubstituted C6 to C40 aryl groups or other substituted or unsubstituted aromatic hydrocarbon groups of C6 to C40 (for example, C6 or more and C20 or less), or combinations thereof.

Examples of organic ligands include thiol compounds such as methanethiol, ethanethiol, propanethiol, butanethiol, pentanethiol, hexanethiol, octanethiol, dodecanethiol, hexadecanethiol, octadecanethiol, benzyl thiol, etc; amines, such as methanamine, ethanamine, propanamine, butanamine, pentylamine, hexylamine, octylamine, nonylamine, decylamine, dodecylamine, hexadecylamine, octadecylamine, dimethylamine, diethylamine, dipropylamine, tributylamine, trioctylamine, and the like; carboxylic acid compounds, such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds, such as methyl phosphine, ethyl phosphine, propyl phosphine, butyl phosphine, pentyl phosphine, octyl phosphine, dioctyl phosphine, tributyl phosphine, trioctyl phosphine, and others; phosphine compounds such as methyl phosphine oxide, ethyl phosphine oxide, propyl phosphine oxide, butyl phosphine oxide pentyl phosphine oxide, tributyl phosphine oxide, octyl phosphine oxide, dioctyl phosphine oxide, trioctyl phosphine oxide, or oxide compounds thereof; diphenylphosphine, triphenylphosphine compounds or oxide compounds thereof; alkyl phosphinic acids of C5 to C20, such as hexylphosphinic acid, octylphosphinic acid, dodecanephosphinic acid, tetradecanephosphinic acid, hexadecanephosphinic acid, octadecanephosphinic acid, and the like; alkyl phosphonic acids of C5 to C20; and the like. Quantum dots may include hydrophobic organic ligands alone or in a mixture of one or more types. Hydrophobic organic ligands may not contain photopolymerizable moieties (e.g., acrylate groups, methacrylate groups, etc.).

The first insulating layer 241 may be located below the bank 210, the wells 212a, 212b, and 212c, the first and second color conversion layers 230a, 230b, and the transmission layer 230c. The first insulating layer 241 may have a shape that covers the bank 210, the wells 212a, 212b, and 212c, the first and second color conversion layers 230a and 230b, and the transmission layer 230c. The first insulating layer 241 may contact the second insulating layer 242 at the wells 212a, 212b, and 212c. The first insulating layer 241 may include an inorganic insulating material such as silicon oxide or silicon nitride.

The adhesive cell gap maintenance layer 400 may be located below the first insulating layer 241. The adhesive cell gap maintenance layer 400 may be located directly on the first insulating layer 241. The adhesive cell gap maintenance layer 400 may combine the display unit 100 and the color conversion unit 200. One display panel may be formed through the adhesive cell gap maintenance layer 400. Some of the adhesive cell gap maintenance layer 400 may be located within the wells 212a, 212b, and 212c. The adhesive cell gap maintenance layer 400 is located on the lower surface of the first and second color conversion layers 230a and 230b or the transmission layer 230c and may form an air gap 420.

The adhesive cell gap maintenance layer 400 may include an adhesive cell gap maintenance part 410 and the air gap 420, and may additionally include the dummy 430.

According to some embodiments, the adhesive cell gap maintenance part 410 may be applied to an area that overlaps at least one of the bank 210, the wells 212a, 212b, 212c, the first and second color conversion layers 230a, 230b, or the transmission layer 230c. For example, it may be applied by overlapping at least one of the bank 210, the wells 212a, 212b, and 212c, the first and second color conversion layers 230a and 230b, or the transmission layer 230c.

The adhesive cell gap maintenance part 410 may include an adhesive organic material 411 and a beads spacer 412. The beads spacer 412 is located within the adhesive organic material 411 and may be surrounded by the adhesive organic material 411, and according to some embodiments, a part of the beads spacer 412 may be exposed to the outside of the adhesive organic material 411. The beads spacer 412 may be in contact with the display unit 100 and the color conversion unit 200 to maintain a gap between them.

The adhesive organic material 411 may include a thermosetting resin. Examples of thermosetting resins include epoxy resins. Epoxy resins may include bisphenol-based, ortho-Cresol novolac-based, multifunctional epoxy, amine-based epoxy, heterocyclic-containing epoxy, substituted epoxy, and naphthol-based epoxy, and more specifically, bisphenol A type epoxy resin, bisphenol F type epoxy resin, hydrogenated bisphenol type epoxy resin, alicyclic epoxy resin, aromatic epoxy resin, novolak type, dicyclopentadiene type epoxy resin, etc., and compounds having these epoxy groups may be used alone or may be used by mixing. Currently commercially available epoxy resins include bisphenolics such as Epiclon 830-S, Epiclon EXA-830CRP, Epiclon EXA 850-S, and Epiclon EXA-850CRP from Nippon Ink Chemical Co, Epiclon EXA-835LV, Epicote 807, Epicote 815, Epicote 825, Epicote 827, Epicote 828, Epicote 834, Epicote 1001, Epicote 1004, Epicote 1007 from Yuka Shell Epoxy Co, Epicote 1009, Dow Chemical's DER-330, DER-301, DER-361, and Kookdo Chemical's YD-128 and YDF-170, and as ortho-cresol novolacs, Kookdo Chemical's YDCN-500-1P, YDCN-500-4P, YDCN-500-5P, and YDCN-500-7P, YDCN-500-80P, YDCN-500-90P, and EOCN-102S, EOCN-103S, EOCN-104S, EOCN-1012, EOCN-1025, and EOCN-1027 from Nippon Chemical Corporation, and Epon 1031S from Yukashell Epoxy Corporation as multifunctional epoxy resins, Araldite 0163 from Shibasu Specialty Chemicals, Inc. and Detacol EX-611, Detacol EX-614, Detacol EX-614B, Detacol EX-622, Detacol EX-512, Detacol EX-521, and Detacol EX-421 from Nagasub Corporation, Detacol EX-411, and Detacol EX-321, and amine-based epoxy resins such as Epicote 604 from Yuka Shell Epoxy, YH-434 from Dokko Chemical, TETRAD-X and TETRAD-C from Mitsubishi Gas Chemical, ELM-120 from Sumitomo Chemical Corporation, PT-810 from Shibasu Specialty Chemical Corporation, and substituted epoxies such as ERL-4234, ERL-4299, ERL-4221, and ERL-4206 from UCC, Naphthol-based epoxies such as Epiclon HP-4032, Epiclon HP-4032D, Epiclon HP-4700, Epiclon 4701, etc. from Daikon Ink Chemical, which may be used alone or in combination with two or more types. To obtain excellent film coating properties, phenoxy resin may be applied, and high-molecular weight resins such as JER's Epicoto 1256, Inchem's PKHH, and Doto Kasei's YP-70 may be applied.

The beads spacer 412 may have a transparent spherical shape. The diameter of the beads spacer 412 may be about 10 μm or less. The beads spacer 412 may be made of resin such as silica or polystyrene.

Referring to FIG. 3, the adhesive cell gap maintenance layer 400 includes a space not filled by the adhesive cell gap maintenance part 410—that is, the air gap 420. Because the refractive index of the air gap 420 is that of air (about 1), it may function as a low-refractive index layer. Through this, light efficiency may be improved. For example, in the embodiments of FIG. 3, the air gap 420 is formed on the second color conversion layer 230b, so the light efficiency of the pixel PXb may be improved. For example, the air gap 420 may be formed on the first and second color conversion layers 230a and 230b or the transmission layer 230c to improve light efficiency.

The dummy 430 is a portion in which the same material as the adhesive cell gap maintenance part 410 is located in the wells 212a, 212b, and 212c, and includes an adhesive organic material 411 and a beads spacer 412. Because the dummy 430 does not overlap the light emitting diode LED on a plane, it may not affect light efficiency and display quality. The beads spacer 412 of the dummy 430 may be exposed to the outside of the adhesive organic material 411.

The second insulating layer 242 may be positioned between the bank 210, the first and second color conversion layers 230a, 230b, the transmission layer 230c, the wells 212a, 212b, and 212c and the color filters 250a, 250b, and 250c. The second insulating layer 242 is located below the color filters 250a, 250b, and 250c, and may be formed while covering the color filters 250a, 250b, and 250c during the process. The second insulating layer 242 flattens the lower surface in contact with the upper surface of the bank 210, the first and second color conversion layers 230a and 230b, the transmission layer 230c, and the wells 212a, 212b, and 212c. The second insulating layer 242 may include an organic insulating material and may be a single layer or a multilayer.

The color filters 250a, 250b, and 250c may overlap the openings of the pixel defining layer 185. The color filters 250a, 250b, and 250c may include the first color filter 250a that transmits light of a first wavelength and absorbs light of other wavelengths, the second color filter 250b that transmits light of a second wavelength and absorbs light of other wavelengths, and the third color filter 250c that transmits light of a third wavelength and absorbs light of other wavelengths.

The first color filter 250a, the second color filter 250b, and the third color filter 250c overlap the first color conversion layer 230a, the second color conversion layer 230b, and the transmission layer 230c, respectively. The first color filter 250a, the second color filter 250b, and the third color filter 250c may correspond to the first pixel PXa, the second pixel PXb, and the third pixel PXc, respectively. Accordingly, it is possible to increase the purity of light of the first wavelength (corresponding to the first pixel PXa), light of the second wavelength (corresponding to the second pixel PXb), and light of the third wavelength (corresponding to the third pixel PXb) that is emitted outside the display panel 10. The first wavelength light, the second wavelength light, and the third wavelength light may be red light, green light, and blue light, respectively.

At the boundaries of the pixels PXa, PXb, and PXc, the first color filter 250a, the second color filter 250b, and the third color filter 250c may overlap each other to form a light blocking area. As shown, the first color filter 250a, the second color filter 250b, and the third color filter 250c may all overlap to form a shading area, but two color filters may also overlap to form a light blocking area. For example, at the boundary between the first pixel PXa and the second pixel PXb, the first color filter 250a and the second color filter 250b may overlap, and at the boundary between the second pixel PXb and the third pixel PXc, the second color filter 250b and the third color filter 250c may overlap, and at the boundary between the third pixel PXc and the first pixel PXa, the third color filter 250c and the first color filter 250a may overlap. The wells 212a, 212b, and 212c are located at the boundaries of the pixels PXa, PXb, PXc, so the first color filter 250a, the second color filter 250b, and the third color filter 250c may overlap each other above the wells 212a, 212b, 212c to form a light blocking area. The first color filter 250a, the second color filter 250b, and the third color filter 250c are stacked on the second insulating layer 242 in that order, but they may be stacked in a different order. Instead of overlapping the color filters 250a, 250b, and 250c, a light blocking area may be provided by forming a light blocking member containing black pigment or dye.

Referring to FIG. 2, an example is shown in which the third well 212c formed in the bank 210 located between adjacent second pixels PXb is divided into a plurality of parts. The third well 212c may include a relatively large first part 212c1 located at the center and a second part 212c2 surrounding the first part 212c1. The first and second parts 212c1 and 212c2 may be partitioned by a bank 210. If the third well 212c is formed to be divided in this way, the parts of the bank 210 including the third well 212c may be connected to form the bank 210 firmly.

Referring to FIG. 3, the position where the adhesive cell gap maintenance part 410 may exist in the adhesive cell gap maintenance layer 400 is shown as the lower surface of the first color conversion layer 230a and the transmission layer 230c. The adhesive cell gap maintenance part 410 is located below the first insulating layer 241. According to some embodiments, the adhesive cell gap maintenance part 410 may be formed at a position overlapping with the second color conversion layer 230b, and may be formed overlapping with at least one of the first or second color conversion layers 230a, 230b or the transmission layer 230c. The air gap 420 filled with air may be formed on the second color conversion layer 230b in which the adhesive cell gap maintenance part 410 is not filled. The light efficiency of the second pixel PXb may be improved due to the air gap 420 formed on the transmission layer 230c.

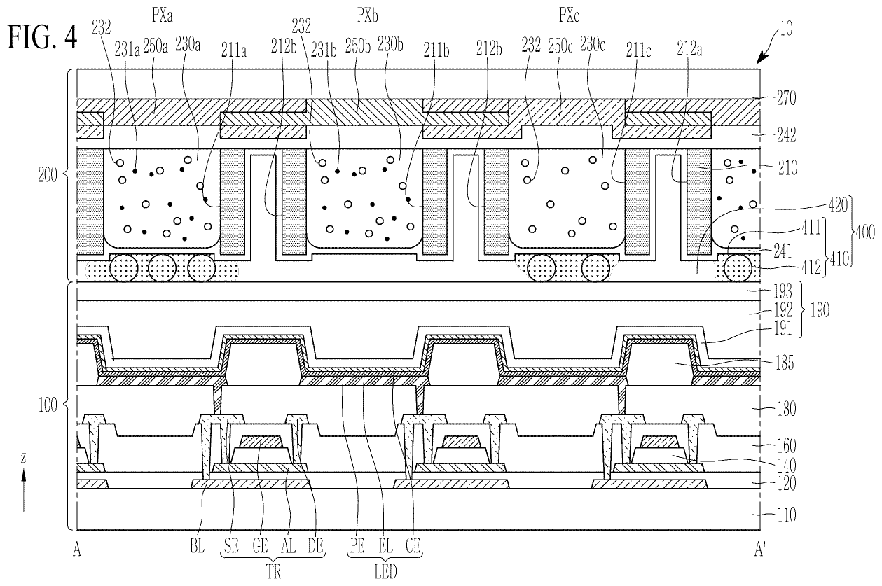

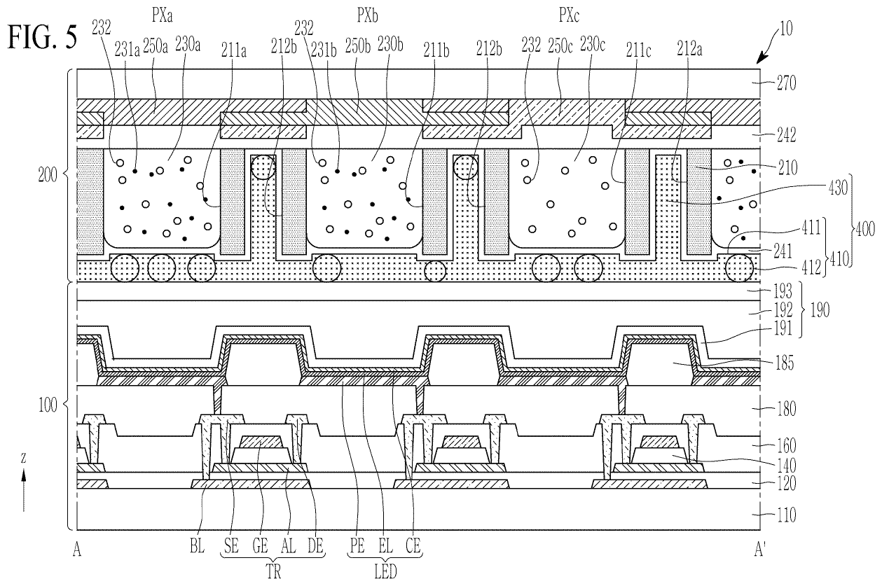

FIG. 4 and FIG. 5 are cross-sectional views taken along the line A-A′ in FIG. 2 according to some embodiments.

First, referring to FIG. 4, it is different from the embodiments of FIG. 3 described above in that the dummy 430 is not formed in the adhesive cell gap maintenance layer 400. The adhesive cell gap maintenance part 410 exists only on the first color conversion layer 230a and the transmission layer 230c. This is formed because the height of the bank 210 is higher than the first color conversion layer 230a and the transmission layer 230c, so that the adhesive cell gap maintenance part 410 does not overflow into the wells 212a and 212b. The adhesive cell gap maintenance part 410 may be formed at a position overlapping the second color conversion layer 230b according to some embodiments, and may be formed overlapping at least one of the first and second color conversion layers 230a, 230b or the transmission layer 230c. As in the embodiments of FIG. 3, the air gap 420 filled with air may be formed above the second color conversion layer 230b, which is an empty space where the adhesive cell gap maintenance part 410 is not filled, and inside the wells 212a, 212b, 212c.

Referring to FIG. 5, embodiments are shown in which the air gap 420 is not formed in the adhesive cell gap maintenance layer 400 and the entire air gap 420 may be filled with the adhesive cell gap maintenance part 410. The adhesive cell gap maintenance part 410 may be formed when a large amount of the inkjet process is applied. The dummy 430 formed inside the wells 212a and 212b may be formed continuously with the adhesive cell gap maintenance part 410. The dummy 430 does not affect light efficiency.

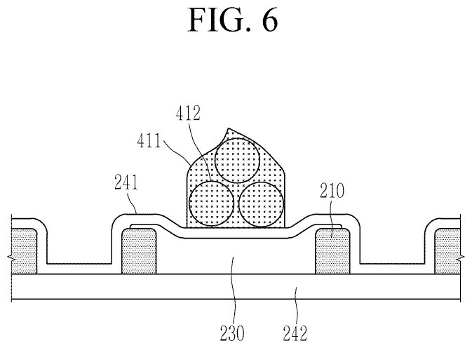

FIG. 6 to FIG. 10 are cross-sectional views schematically showing the manufacturing process of the display panel 10 according to some embodiments.

FIGS. 6 to 10 may illustrate a manufacturing process of the display panel 10 shown in FIG. 3.

Referring to FIG. 6, the process involves first forming the first and second color conversion layers 230a, 230b, the transmission layer 230c, the wells 212a, 212b, 212c, and the bank 210 on the second insulation layer 242, and then covering them with the first insulation layer 241. Next, the adhesive cell gap maintenance part 410 is applied on the first insulating layer 241. At this time, the location where the adhesive cell gap maintenance part 410 is applied is at least one of the first or second color conversion layers 230a or 230b or the transmission layer 230c, other than the bank 210 and the wells 212a, 212b, and 212c. The adhesive cell gap maintenance part 410 is formed through an inkjet process. The adhesive cell gap maintenance part 410 is a mixture of the adhesive organic material 411 and the beads spacer 412.

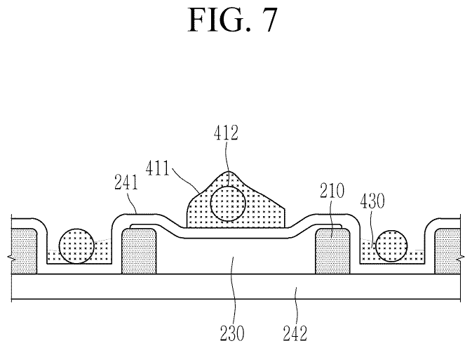

Referring to FIG. 7, in the step of applying the adhesive cell gap maintenance part 410, a portion of the adhesive cell gap maintenance part 410 overflows into the wells 212a, 212b, and 212c to form the dummy 430. Because the dummy 430 is not positioned to overlap the light emitting diode LED on a plane but is overlapped and obscured by the overlapping color filters 250a, 250b, and 250c, it may not affect light efficiency and display quality.

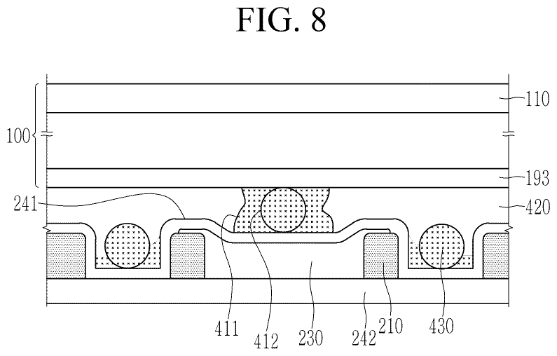

Referring to FIG. 8, after the display unit 100 formed on the lower substrate 110 is bonded, the applied adhesive cell gap maintenance part 410 and the dummy 430 overflowing the wells 212a, 212b, and 212c are cured together. The air gap 420 is formed in a space where the adhesive cell gap maintenance part 410 does not exist. The beads spacer 412 located on the first and second color conversion layers 230a, 230b or the transmission layer 230c is connected to the second inorganic layer 193 of the display unit 100 and the first color conversion unit 200, and is in contact with the first insulating layer 241 to maintain a gap between the display unit 100 and the color conversion unit 200. Because the dummy 430 does not overlap the light emitting diode LED on a plane, it may not affect light efficiency or display quality. In the embodiments of FIG. 8, the display unit 100 represents the lower substrate 110 and the second inorganic layer 193 by necessarily omitting some of the components of the display unit 100 in the embodiments of FIG. 3.

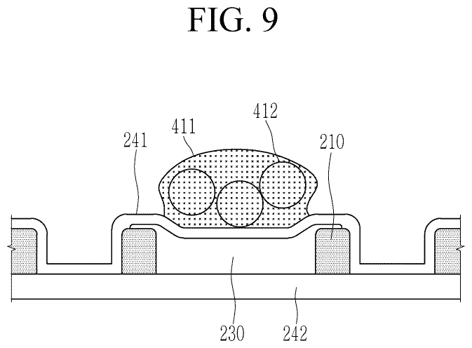

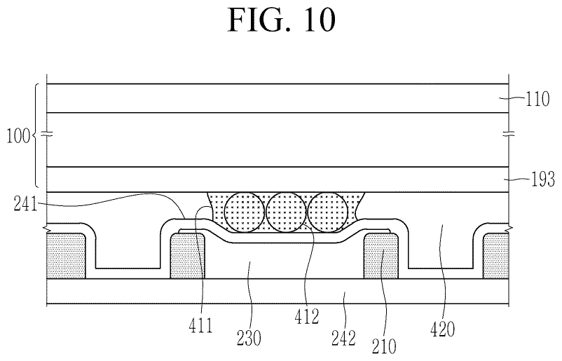

Hereinafter, modified embodiments of FIGS. 7 and 8 will be examined through FIGS. 9 and 10.

FIG. 9 and FIG. 10 show a manufacturing process of the display panel 10 according to some embodiments.

Referring to FIG. 9, there is a difference from the above-described embodiments as to whether or not the dummy 430 is formed. After applying the adhesive cell gap maintenance part 410, the height of the bank 210 is formed higher than the first and second color conversion layers 230a, 230b or the transmission layer 230c, so that it does not overflow into the wells 212a, 212b, 212c. In other words, it does not form the dummy 430.

Referring to FIG. 10, after the display unit 100 formed on the lower substrate 110 is bonded, the applied adhesive cell gap maintenance part 410 is cured. The air gap 420 is formed in a space where the adhesive cell gap maintenance part 410 does not exist. The beads spacer 412 located above the first and second color conversion layers 230a, 230b or the transmission layer 230c is in contact with the second inorganic layer 193 of the display unit 100 and the first insulating layer 241 of the color conversion unit 200, maintaining the gap between the display unit 100 and the color conversion unit 200. In the embodiments of FIG. 10, the display unit 100 represents the lower substrate 110 and the second inorganic layer 193 by necessarily omitting some of the components of the display unit 100 in the embodiments of FIG. 3.

As shown in FIGS. 6 to 10, the adhesive organic material 411 and the beads spacer 412 are located at once through an inkjet process, which has the effect of simplifying the process and reducing costs. By adjusting the specific gravity of the bead spacer 412 present in the droplet of the adhesive cell gap maintenance part 410 to be applied and the number of applications, the amount of material consumed, the time required for the manufacturing process and the like may be reduced.

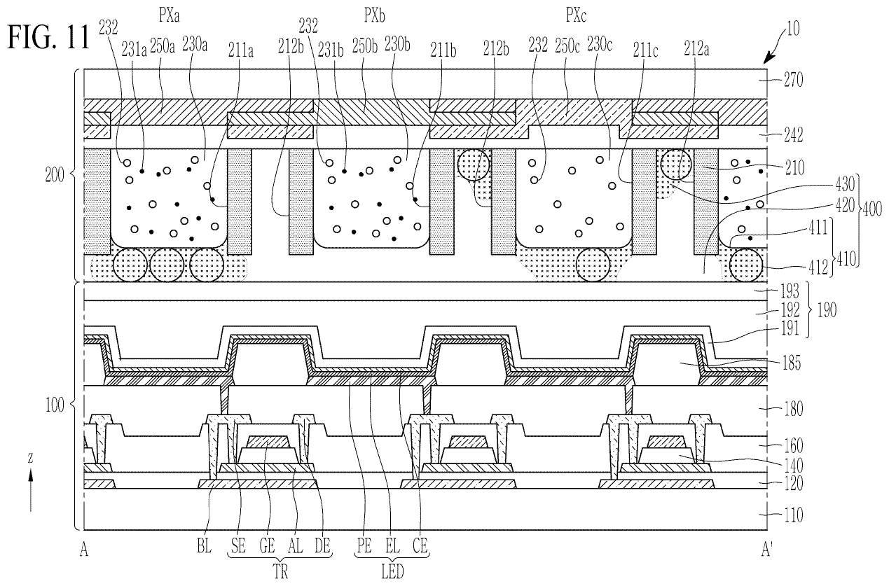

Hereinafter, modified embodiments of FIGS. 3 to 5 will be examined through FIGS. 11 to 13. Descriptions of the same components as those described in FIGS. 3 to 5 will be omitted.

FIG. 11 to FIG. 13 are cross-sectional views taken along the line A-A′ in FIG. 2 according to some embodiments.

Referring to FIGS. 11 to 13, there is a difference in that the first insulating layer 241 is excluded from the above-described embodiments of FIGS. 3 to 5, and even if the adhesive cell gap maintenance part 410 and the first and second color conversion layers 230a and 230b and the transmission layer 230c is formed and cured, the effect on display quality is minimal.

In FIG. 11 to FIG. 13, the adhesive cell gap maintenance part 410 is applied directly over the corners of the first and second color conversion layers 230a and 230b, the transmission layer 230c, or the bank 210. Through this, the liquid repellency of the bank 210 may be exhibited with respect to the adhesive cell gap maintenance part 410. For example, during the inkjet process for forming the adhesive cell gap maintenance layer 400, the spreadability of droplets misdeposited on or at the corners of the bank 210 is controlled to prevent or reduce retention on the bank 210, at the corners of the bank 210, or in the well 212, and to reduce the size of the misdeposited droplets. If there is a misdeposited droplet, it may interfere with the formation of the air gap 420 and thus increase or decrease the light efficiency, so it may be necessary to remove it or reduce its size. As a way to reduce misdeposited droplets, the height of the bank 210 may be set higher than the first and second color conversion layers 230a and 230b and the transmission layer 230c.

Referring to FIG. 11, the location where the adhesive cell gap maintenance part 410 may exist in the adhesive cell gap maintenance layer 400 is shown as the lower surface of the first color conversion layer 230a and the transmission layer 230c. Because there is no first insulating layer 241, the adhesive cell gap maintenance part 410 directly contacts the first color conversion layer 230a and the transmission layer 230c. According to some embodiments, the adhesive cell gap maintenance part 410 may be formed at a position overlapping the second color conversion layer 230b, and may be formed overlapping at least one of the first or second color conversion layers 230a, 230b or the transmission layer 230c. The air gap 420 filled with air may be formed on the second color conversion layer 230b in which the adhesive cell gap maintenance part 410 is not filled.

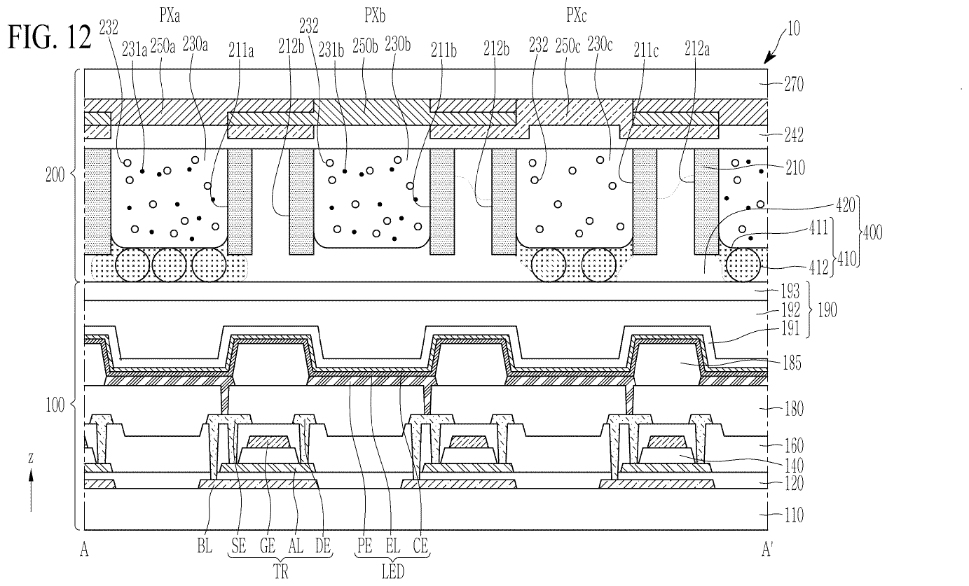

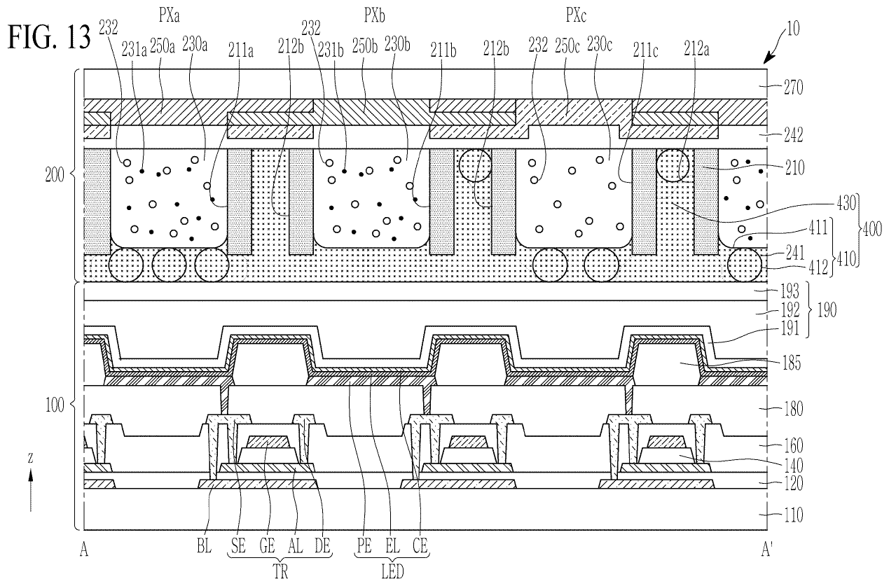

FIGS. 12 and 13 are cross-sectional views taken along the line A-A′ in FIG. 2 according to some embodiments.

First, referring to FIG. 12, it is different from the above-described embodiments of FIG. 11 in that the dummy 430 is not formed in the adhesive cell gap maintenance layer 400. The adhesive cell gap maintenance part 410 exists only on the first color conversion layer 230a and the transmission layer 230c. This is formed by controlling the spread of misdeposited droplets due to the liquid repellency of the bank 210. The adhesive cell gap maintenance part 410 may be formed at a position overlapping the second color conversion layer 230b according to some embodiments, and may be formed by overlapping at least one of the first or second color conversion layers 230a, 230b or the transmission layer 230c. As in the embodiments of FIG. 11, the air gap 420 filled with air is formed above the second color conversion layer 230b, which is an empty space where the adhesive cell gap maintenance part 410 is not filled, and inside the wells 212a, 212b, 212c.

Referring to FIG. 13, embodiments are shown in which the air gap 420 is not formed in the adhesive cell gap maintenance layer 400 and the entire air gap 420 may be filled with the adhesive cell gap maintenance part 410. The adhesive cell gap maintenance part 410 may be formed when a large amount of the inkjet process is applied. The dummy 430 formed inside the wells 212a and 212b may be formed continuously with the adhesive cell gap maintenance part 410. The dummy 430 does not affect light efficiency.

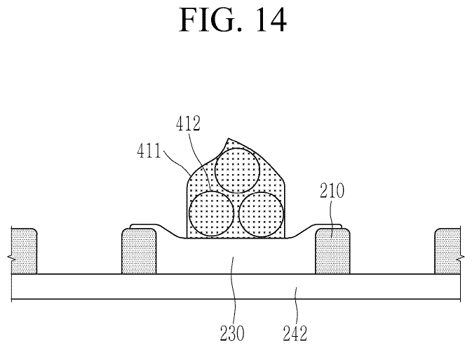

Hereinafter, modified embodiments of FIGS. 6 to 10 will be examined through FIGS. 14 to 18.

FIG. 14 to FIG. 18 are cross-sectional views schematically showing the manufacturing process of a display panel according to some embodiments.

Referring to FIGS. 14 to 18, there is a difference in that the first insulating layer 241 is excluded from the above-described embodiments of FIGS. 6 to 10.

Referring to FIG. 14, first, the process is performed to form the first and second color conversion layers 230a, 230b, the transmission layer 230c, the wells 212a, 212b, 212c, and the bank 210 on the second insulation layer 242. Next, the adhesive cell gap maintenance part 410 is applied on at least one of the first or second color conversion layers 230a or 230b or the transmission layer 230c. Through this, the liquid repellency of the bank 210 may be exhibited with respect to the adhesive cell gap maintenance part 410. The adhesive cell gap maintenance part 410 is formed through an inkjet process. The adhesive cell gap maintenance part 410 is an adhesive organic material 411 mixed with the beads spacer 412.

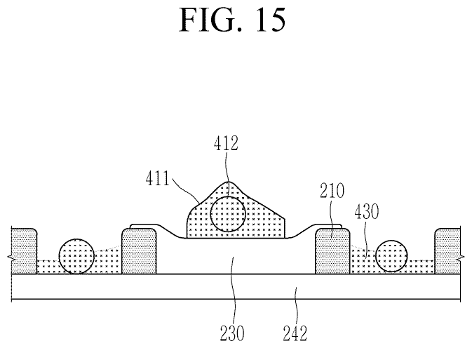

Referring to FIG. 15, in the step of applying the adhesive cell gap maintenance part 410, a portion of the adhesive cell gap maintenance part 410 overflows into the wells 212a, 212b, and 212c to form the dummy 430. In this way, if the liquid repellency of the bank 210 is insufficient and the amount applied is large, the dummy 430 may be formed.

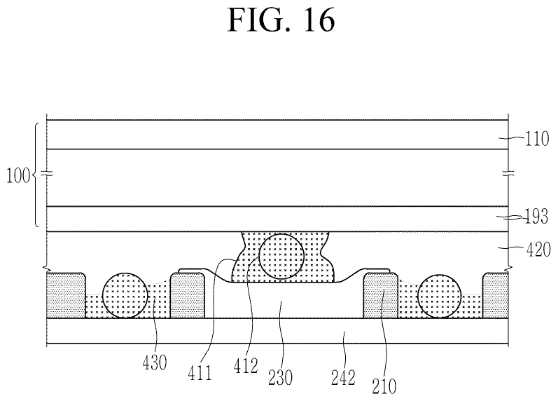

Referring to FIG. 16, after the display unit 100 formed on the lower substrate 110 is bonded, the applied adhesive cell gap maintenance part 410 and the dummy 430 overflowing into the wells 212a, 212b, and 212c are cured together. The air gap 420 is formed in a space where the adhesive cell gap maintenance part 410 does not exist. The beads spacer 412 located directly above the first and second color conversion layers 230a, 230b or the transmission layer 230c is in contact with the second inorganic layer 193 of the display unit 100 and maintains the gap between the display unit 100 and the color conversion unit 200. In the embodiments of FIG. 16, the display unit 100 represents the lower substrate 110 and the second inorganic layer 193 by necessarily omitting some of the components of the display unit 100 in the embodiments of FIG. 3.

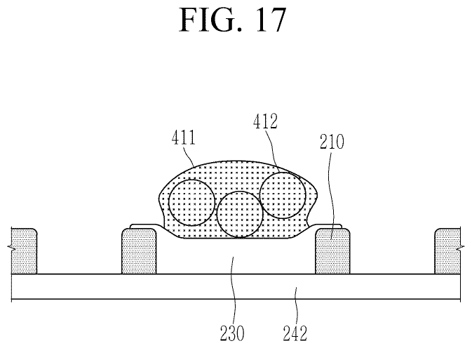

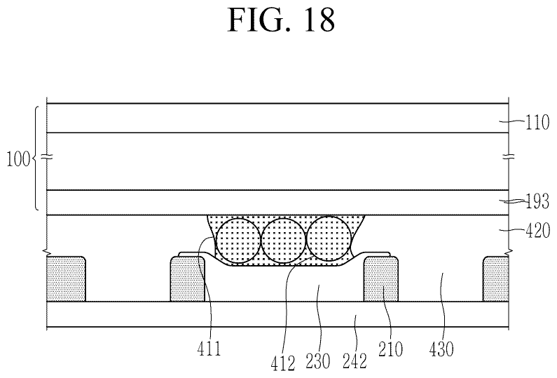

Hereinafter, modified embodiments of FIGS. 15 and 16 will be examined through FIGS. 17 and 18.

FIG. 17 and FIG. 18 show a manufacturing process of the display panel 10 according to some embodiments.

Referring to FIG. 17, there is a difference from the above-described embodiments as to whether or not the dummy 430 is formed. The applied adhesive cell gap maintenance part 410 does not overflow into the wells 212a, 212b, and 212c due to the liquid repellency of the bank 210. In other words, it does not form the dummy 430. The liquid repellency of the bank 210 may be provided by using a photosensitive organic material containing a liquid-repellent material in the bank 210 or by making the surface of the bank 210 lyophobic.

Referring to FIG. 18, after the display unit 100 formed on the lower substrate 110 is bonded, the applied adhesive cell gap maintenance part 410 is cured. The air gap 420 is formed in a space where the adhesive cell gap maintenance part 410 does not exist. The beads spacer 412 positioned above the first and second color conversion layers 230a, 230b or the transmission layer 230c contacts the second inorganic layer 193 of the display unit 100 and the first insulating layer 241 of the color conversion unit 200, maintaining the gap between the display unit 100 and the color conversion unit 200. In the embodiments of FIG. 18, the display unit 100 represents the lower substrate 110 and the second inorganic layer 193 by necessarily omitting some of the components of the display unit 100 in the embodiments of FIG. 3.

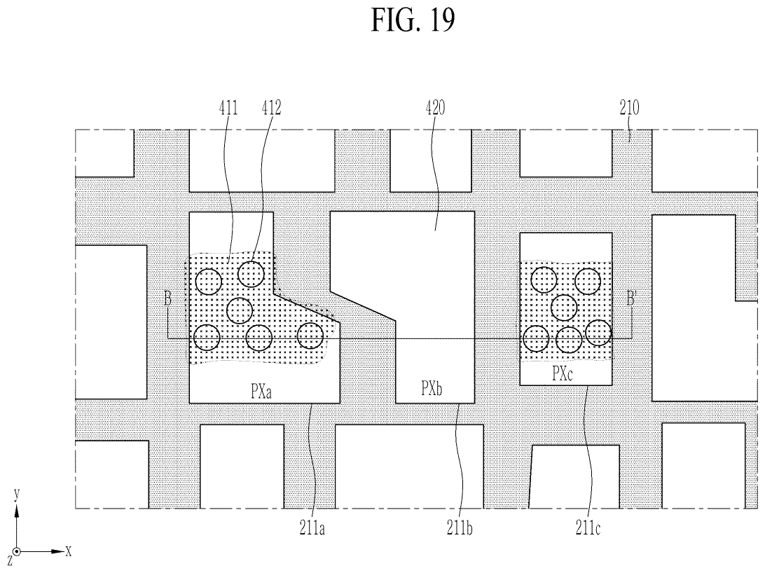

Hereinafter, a display panel according some embodiments will be described with reference to FIGS. 19 to 21. Some repetitive descriptions of some components that are the same as those described in FIG. 2 may be omitted.

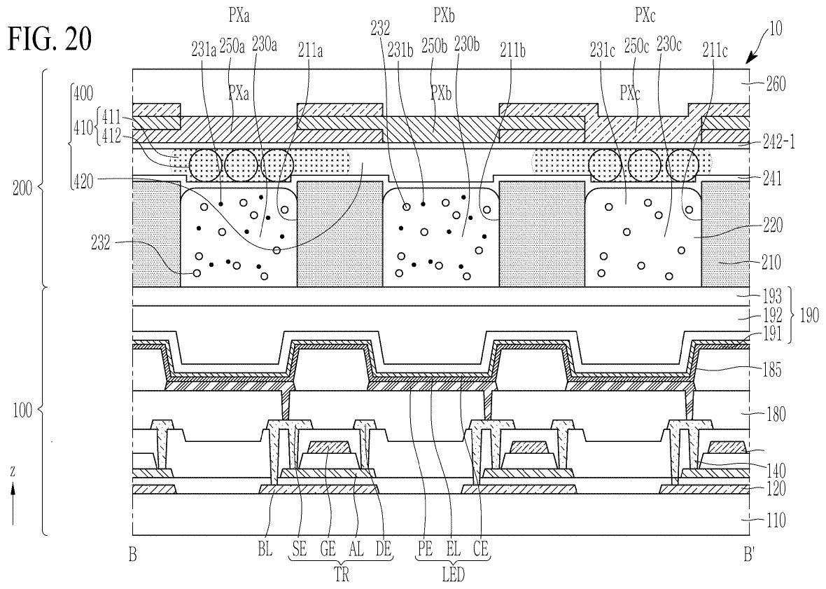

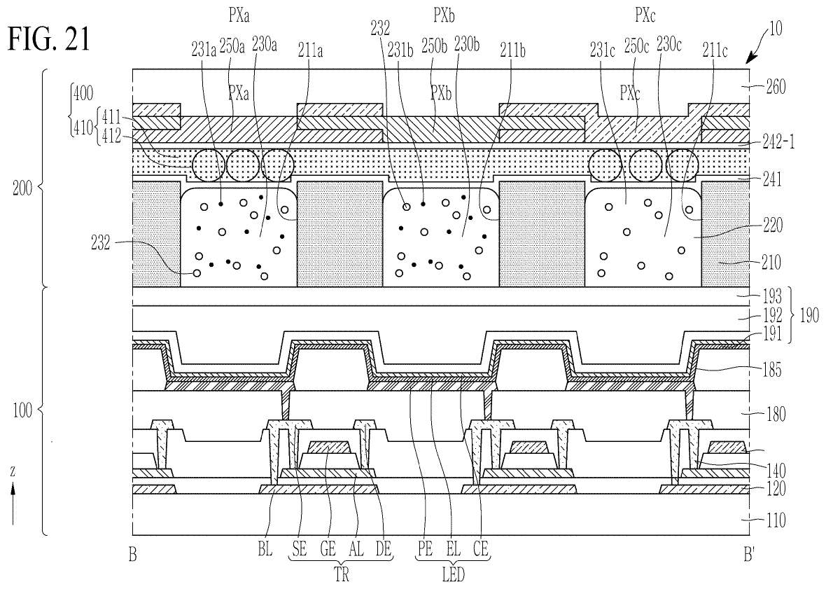

FIG. 19 is a schematic plan view of a display area in a display panel according to some embodiments, and FIGS. 20 and 21 are cross-sectional views taken along the line B-B′ in FIG. 19 according to some embodiments.

Referring to FIG. 19, the structure of the bank 210 is different from the above-described embodiments.

The bank 210 may not include wells 212a, 212b, and 212c. In other words, the openings 211a, 211b, 211c may be included by the bank 210.

Referring to FIG. 20, the color conversion unit 200 may include a bank 210, first and second color conversion layers 230a, 230b, a transmission layer 230c, first and second-1 insulating layers 241, 242-1, an adhesive cell gap maintenance layer 400, color filters 250a, 250b, 250c, and an overcoat layer 260.

The bank 210 may be located on the encapsulation layer 190. For example, the lower surface of the bank 210 may contact the upper surface of the encapsulation layer 190. The lower surfaces of the first color conversion layer 230a, the second color conversion layer 230b, and the transmission layer 230c may contact the upper surface of the encapsulation layer 190.

Because there are no wells 212a, 212b, 212c, the adhesive cell gap maintenance layer 400 may be applied to at least one of the bank 210, the first and second color conversion layers 230a, 230b, or the transmission layer 230c. The adhesive cell gap maintenance part 410 may be applied on the first insulating layer 241. For example, it may be applied to overlap on at least one of the bank 210, the first and second color conversion layers 230a, 230b, or the transmission layer 230c.

In the adhesive cell gap maintenance layer 400, the air gap 420 may be formed in a space not filled by the adhesive cell gap maintenance part 410. However, because there are no wells 212a, 212b, 212c, the adhesive cell gap maintenance part 410 may not include the dummy 430.

The second-1 insulating layer 242-1 is located on the adhesive cell gap maintenance layer 400. The second-1 insulating layer 242-1 may immediately cover the bank 210, the first and second color conversion layers 230a and 230b, and the transmission layer 230c. The second-1 insulating layer 242-1 may include an inorganic insulating material such as silicon oxide or silicon nitride.

The color filters 250a, 250b, 250c may be formed on the adhesive cell gap maintenance layer 400. The color filters 250a, 250b, 250c may be formed on the second-1 insulating layer 242-1.

The overcoat layer 260 may be positioned on the color filters 250a, 250b, 250c. The overcoat layer may include an inorganic insulating material and/or an organic insulating material and may be a single layer or multiple layers. An anti-reflection layer that reduces external light reflection may be positioned on the overcoat layer 260.

Referring to FIG. 21, embodiments are shown in which no air gap 420 is formed in the adhesive cell gap maintenance layer 400, and the entire air gap 420 may be filled with the adhesive cell gap maintenance part 410. The adhesive cell gap maintenance part 410 may be formed when a large amount of the inkjet process is applied.

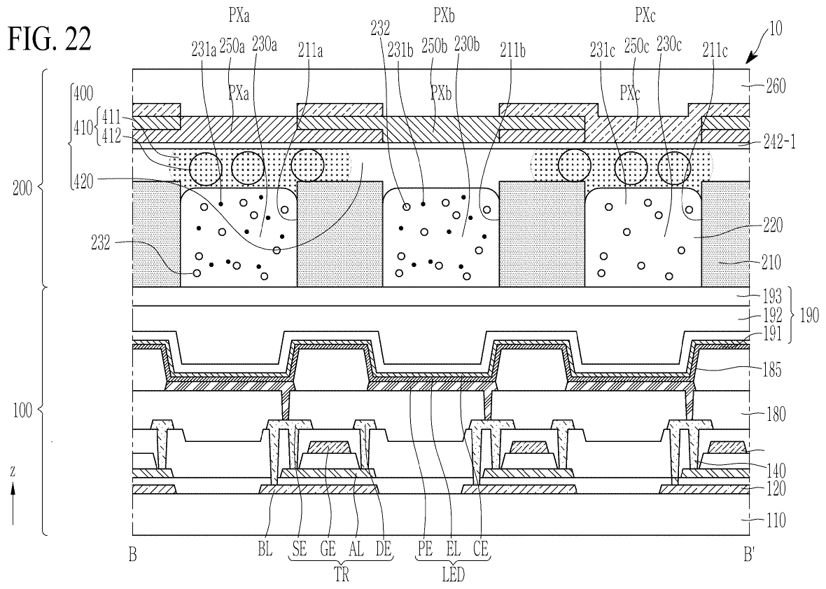

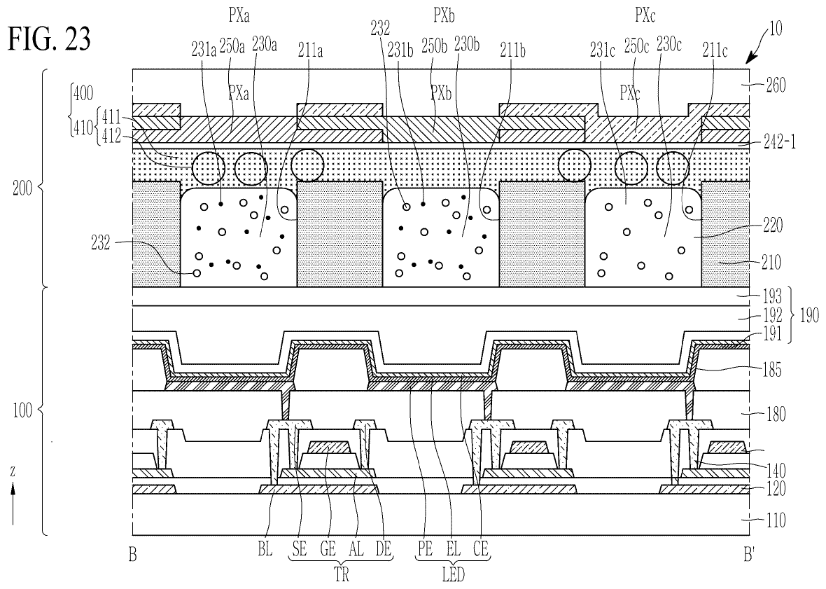

Hereinafter, a cross-sectional view of a display panel according to some embodiments will be looked at with reference to FIGS. 22 and 23. Some repetitive descriptions of the same components as those described in FIG. 19 may be omitted.

FIGS. 22 and 23 are cross-sectional views taken along the line B-B′ in FIG. 19 according to some embodiments.

In FIG. 22 and FIG. 23, the first insulating layer 241 may be excluded from FIGS. 20 and 21. Referring to FIGS. 22 and 23, the first insulating layer 241 may be excluded and the adhesive cell gap maintenance part 410 may be applied on the bank 210 or just above the edge. In other words, the liquid repellency of the bank 210 may be exhibited with respect to the adhesive cell gap maintenance part 410. The second-1 insulating layer 242-1 may be present in contact with the lower surfaces of the color filters 250a, 250b, 250c.

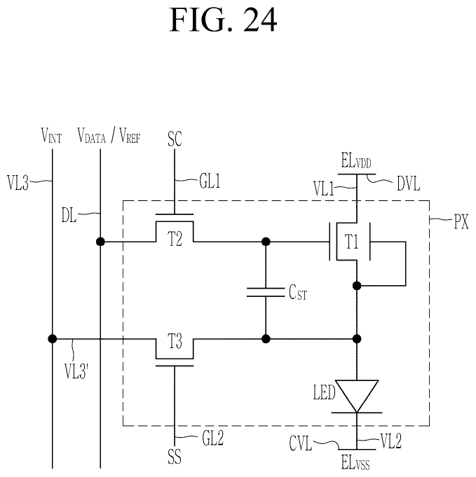

Hereinafter, the structure of a pixel according to some embodiments will be examined through a circuit with reference to FIG. 24.

FIG. 24 is a circuit diagram of one pixel of the display device according to some embodiments.

Referring to FIG. 24, one pixel PX may include first to third transistors T1-T3, a storage capacitor CST, and a light emitting diode LED. Light emitting diodes LEDs may be organic or inorganic light emitting diodes. The first to third transistors T1-T3 may be n-type transistors, and at least some of them may be p-type transistors.

The gate electrode of the first transistor T1 may be connected to the first electrode of the storage capacitor CST. The first electrode of the first transistor T1 may be connected to the driving voltage line VL1 that delivers the driving voltage ELVDD, and the second electrode of the first transistor T1 may be connected to the anode of the light emitting diode LED and the second electrode of the storage capacitor CST.

The first transistor T1 may receive a data voltage VDATA according to the switching operation of the second transistor T2 and supply a driving current to the light emitting diode LED according to the voltage stored in the storage capacitor CST.

The gate electrode of the second transistor T2 may be connected to a first gate line GL1 that transmits a first scan signal SC. The first electrode of the second transistor T2 may be connected to a data line DL capable of transmitting the data voltage VDATA or the reference voltage. The second electrode of the second transistor T2 may be connected to the first electrode of the storage capacitor CST and the gate electrode of the first transistor T1. The second transistor T2 may be turned on according to the first scan signal SC to transmit the reference voltage or data voltage VDATA to the gate electrode of the first transistor T1.

The gate electrode of the third transistor T3 may be connected to the second gate line GL2 that transmits a second scan signal SS. The first electrode of the third transistor T3 may be connected to the second electrode of the storage capacitor CST and the second electrode and anode of the first transistor T1. The second electrode of the third transistor T3 may be connected to the initialization voltage line VL3 that transmits the initialization voltage VINT. The third transistor T3 may be turned on according to the second scan signal SS and transfer the initialization voltage VINT to the anode to initialize the voltage of the anode.

The first electrode of the storage capacitor CST may be connected to the gate electrode of the first transistor T1, and the second electrode of the storage capacitor CST may be connected to the first electrode and anode of the third transistor T3. The cathode of the light emitting diode LED may be connected to the common voltage line VL2 that transmits the common voltage ELVSS. Each light emitting diode LED may constitute one pixel PX, and the anode and cathode of the light emitting diode LED may be called a pixel electrode and a common electrode, respectively.

A light emitting diode LED may emit light with a brightness (gradation) according to the driving current generated by the first transistor T1.

An example of the operation of the circuit shown in FIG. 24, particularly the operation during one frame, will be described by taking the case where the transistors T1-T3 are all n-type channel transistors.

When one frame starts, a high-level first scan signal SC and the high-level second scan signal SS are supplied in the initialization period, so that the second transistor T2 and the third transistor T3 may be turned on. A reference voltage VREF from the data line DL may be supplied to the gate electrode of the first transistor T1 and the first electrode of the storage capacitor CST through the turned-on second transistor T2, and the initialization voltage VINT may be supplied to the second electrode and anode of the first transistor T1 through the turned on third transistor T3. Accordingly, during the initialization period, the anode may be initialized to the initialization voltage VINT. The voltage difference between the reference voltage VREF and the initialization voltage VINT may be stored in the storage capacitor CST.

Next, when the second scan signal SS reaches a low level while the first scan signal SC is maintained at a high level in the sensing period, the second transistor T2 may remain turned on and the third transistor T3 may be turned off. When the second transistor T2 is turned on, the gate electrode of the first transistor and the first electrode of the storage capacitor CST may maintain the reference voltage, and when the third transistor T3 is turned off, the second electrode and the anode of the first transistor may be disconnected from the initialization voltage VINT.

Accordingly, current flows from the first electrode of the first transistor T1 to the second electrode, and when the voltage of the second electrode becomes a “reference voltage-threshold voltage,” the first transistor T1 may be turned off. Here, the threshold voltage is the threshold voltage of the first transistor T1. At this time, the voltage difference between the gate electrode and the second electrode of the first transistor T1 may be stored in the storage capacitor CST, and sensing of the threshold voltage of the first transistor T1 may be completed. By generating a compensated data signal by reflecting the characteristic information sensed during the sensing period, the characteristic deviation of the first transistor T1, which may be different for each pixel PX, may be compensated.

Next, when the high-level first scan signal SC is supplied and the low-level second scan signal SS is supplied in the data input section, the second transistor T2 may be turned on and the third transistor T3 may be turned off. The data voltage VDATA from the data line DL may be supplied to the gate electrode of the first transistor T1 and the first electrode of the storage capacitor CST through the turned-on second transistor T2. The data voltage VDATA may have a compensated value based on sensing the threshold voltage of the first transistor T1, and through this, the characteristic deviation of the first transistor T1 may be corrected. When the data voltage VDATA is applied, the second electrode and anode of the first transistor T1 may maintain substantially the same potential in the sensing section due to the first transistor T1 being turned off.

Next, in the light emitting section, the first transistor T1, which is turned on by the data voltage VDATA delivered to the gate electrode of the first transistor, may generate a driving current according to the data voltage VDATA, and the light emitting diode LED may emit light by this driving current.

That is, the brightness of the light emitting diode LED may be adjusted by adjusting the driving current applied to the light emitting diode LED according to the size of the data voltage VDATA applied to the pixel PX.

Although aspects of some embodiments of the present disclosure have been described in detail above, the scope of embodiments according to the present disclosure is not limited thereto, and various modifications and improvements made by those skilled in the art using the disclosed embodiments of the present disclosure as defined in the following claims, and their equivalents, are also possible.

Description of Some of the Reference Symbols

| | |
|---|---|
| 1: display device | 10: display panel |
| 100: display unit | 110: lower substrate |
| 185: pixel defining layer | 90: display encapsulation |
| | layer |
| 200: color conversion unit | 210: bank |
| 211a, 211b, 211c: opening | 212a, 212b, 212c: well |
| 230a, b: first and second color conversion | 230c: transmission layer |
| layer | |
| 231a, 231b: quantum dot | 232: scatterer |
| 241, 242, 242-1: first, second and second-1 | |
| insulating layer | |
| 250a, 250b, 250c: first, second, third color | |
| filter | |
| 260: overcoat layer | 270: upper substrate |
| 400: adhesive cell gap maintenance layer | |
| 410: adhesive cell gap maintenance part | |
| 411: adhesive organic material | 412: beads spacer |
| 420: air gap | 430: dummy |
| DA: display area | LED: light emitting diode |
| NA: non-display area | |
| PX, PXa, PXb, PXc: pixel | T1, T2, T3, TR: transistor |

What is claimed is:

1. A display device, comprising:
a display unit including a plurality of light emitting diodes;
a color conversion unit including a bank and a color conversion layer; and
an adhesive cell gap maintenance layer between the display unit and the color conversion unit,
wherein the adhesive cell gap maintenance layer includes an adhesive cell gap maintenance part, and
the adhesive cell gap maintenance part includes a beads spacer and an adhesive organic material.

2. The display device of claim 1, wherein:
the color conversion unit further includes a transmission layer, and
the adhesive cell gap maintenance part is on at least one of the color conversion layer or the transmission layer.

3. The display device of claim 2, wherein a portion of the adhesive cell gap maintenance part includes the adhesive cell gap maintenance layer overlapping the bank.

4. The display device of claim 2, wherein:
the color conversion unit further includes a well, and
the adhesive cell gap maintenance part is within the well.

5. The display device of claim 2, wherein an air gap is formed in a portion of the adhesive cell gap maintenance layer where the adhesive cell gap maintenance part is not filled.

6. The display device of claim 1, wherein a height of the bank is higher than a height of the color conversion layer.

7. The display device of claim 1, wherein the adhesive cell gap maintenance part contacts the color conversion layer and the bank.

8. The display device of claim 1, wherein:
the color conversion unit further includes a transmission layer,
the color conversion layer includes quantum dots and scatterers, and the transmission layer include scatterers.

9. A display device, comprising:
a substrate;
a plurality of light emitting diodes on the substrate;
an encapsulation layer on the plurality of light emitting diodes;
a color conversion unit including a bank and a color conversion layer on the encapsulation layer;
an adhesive cell gap maintenance part including a beads spacer and an adhesive organic material on the color conversion unit;
an adhesive cell gap maintenance layer including the adhesive cell gap maintenance part; and
a color filter on the adhesive cell gap maintenance layer.

10. The display device of claim 9, wherein:
the color conversion unit further includes a transmission layer, and
the adhesive cell gap maintenance part is on at least one of the color conversion layer or the transmission layer.

11. The display device of claim 10, wherein a portion of the adhesive cell gap maintenance part includes the adhesive cell gap maintenance layer overlapping the bank.

12. The display device of claim 10, wherein an air gap is formed in a portion of the adhesive cell gap maintenance layer where the adhesive cell gap maintenance part is not filled.

13. The display device of claim 9, wherein a height of the bank is higher than a height of the color conversion layer.

14. The display device of claim 9, wherein the adhesive cell gap maintenance part contacts the color conversion layer and the bank.

15. The display device of claim 9, wherein:
the color conversion unit further includes a transmission layer,
the color conversion layer includes quantum dots and scatterers, and the transmission layer includes scatterers.

16. A method of manufacturing a display device, the method comprising:
forming a bank including a color conversion layer and a transmission layer;
applying an adhesive cell gap maintenance part including a beads spacer and an adhesive organic material on at least one of the color conversion layer or the transmission layer;
bonding a display unit onto the adhesive cell gap maintenance part; and
curing the adhesive cell gap maintenance part to form an adhesive cell gap maintenance layer.

17. The method of manufacturing the display device of claim 16, wherein:
in curing the adhesive cell gap maintenance part, the adhesive cell gap maintenance layer is formed on any one of the color conversion layer, the transmission layer, or the bank.

18. The method of manufacturing the display device of claim 17, wherein:
in curing the adhesive cell gap maintenance part, a portion of the adhesive cell gap maintenance part overlaps the bank to form the adhesive cell gap maintenance layer.

19. The method of manufacturing the display device of claim 17, wherein:
the bank further includes a well,
in curing the adhesive cell gap maintenance part, a portion of the adhesive cell gap maintenance part remains in the well and forms the adhesive cell gap maintenance layer.

20. The method of manufacturing the display device of claim 17, wherein:
in curing the adhesive cell gap maintenance part, an air gap is formed in a space not filled by the adhesive cell gap maintenance part.
